(19) United States
(12) Patent Application Publication
(10) Pub. No.: US 2007/0170511 A1
(43) Pub. Date: Jul. 26, 2007

(54) METHOD FOR FABRICATING A RECESSED-GATE MOS TRANSISTOR DEVICE

(76) Inventor: Ming-Yuan Huang, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 11/466,461

(22) Filed: Aug. 23, 2006

(30) Foreign Application Priority Data
Jan. 24, 2006 (TW) 095102698

(51) Int. Cl. H01L 23/62

(52) U.S. Cl. 257/355

(57) ABSTRACT

A method of fabricating a recess-gate transistor is provided. A first liner and a dielectric layer are formed on a substrate. An opening is formed in the first liner and dielectric layer. A second liner is formed on the dielectric layer and in the opening. The second liner is dry-etched to form a sidewall spacer in the opening. The substrate is recess etched to form a gate trench. A gate oxide layer is formed on in the gate trench. The gate trench is filled with gate material layer and then etched back. A capping metal layer and a dielectric cap layer are formed on the gate material layer. The dielectric layer is stripped.

### BACKGROUND OF THE INVENTION

1. Field of the Invention

The present invention relates generally to method of fabricating a semiconductor device and, more particularly, to a method for fabricating a recessed-gate metal-oxide-semiconductor (MOS) transistor device.

2. Description of the Prior Art

With the continuing shrinkage of device feature size, the so-called short channel effect (SCE) due to shrunk gate channel length has been found that it can hinder the integrity of integrated circuit chips. Many efforts have been made for solving this problem, for example, by reducing the thickness of the gate oxide dielectric or by increasing the doping concentration of source/drain. However, these approaches adversely affect the device reliability and speed of data transfer on the other hand, and are thus impractical.

A newly developed recessed-gate MOS transistor becomes most promising. In the filed of Dynamic Random Access Memory (DRAM), the recessed-gate technology may be used to improve the integrity of the memory chip. Typically, the recess-gate MOS transistor has a gate insulation layer formed on sidewalls and bottom surface of a recess etched into a substrate, a conductive filling the recess, contrary to a planar gate type transistor having a gate electrode formed on a planar surface of a substrate.

However, the aforesaid recess-gate MOS transistor has some shortcomings. According to the prior art method, in order to form the recess gate MOS transistor, a first lithographic and etching process is first performed to etch a gate trench into a main surface of a semiconductor substrate. After filling the gate trench with a gate material layer, a second lithographic and etching process is performed to define a gate conductor (GC) on the recess gate. It required two masks to define the gate trench and the GC and is therefore costly. The misalignment between the GC and the recess gate of the recess-gate MOS transistor device also becomes a real challenge.

### SUMMARY OF THE INVENTION

It is one object of this invention to provide a method of fabricating a recess-gate MOS transistor device in order to solve the above-mentioned problems.

According to the claimed invention, a method for fabricating a recessed-gate transistor device is disclosed. A dielectric layer is formed on a semiconductor substrate. The dielectric layer is patterned to form an opening exposing a portion of the semiconductor substrate. The opening has a bottom and a sidewall. A liner is formed on the bottom and the sidewall in the opening. A dry etching process is performed to etch the liner at the bottom in the opening, thereby forming a spacer on the sidewall in the opening. The semiconductor substrate is etched to form a gate trench having a trench bottom and trench sidewall. A gate oxide layer is formed on the trench bottom and trench sidewall. A gate material layer is formed on the spacer and on the gate oxide layer in the gate trench. A metal layer is formed on the gate material layer. A cap layer is formed on the metal layer. Finally, the dielectric layer is removed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-8 are schematic, cross-sectional diagrams illustrating a method of fabricating a recess-gate MOS transistor in accordance with one preferred embodiment of this invention.

### DETAILED DESCRIPTION

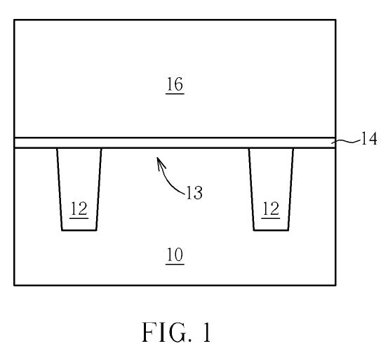

FIGS. 1-8 are schematic, cross-sectional diagrams illustrating a method of fabricating a recess-gate MOS transistor in accordance with one preferred embodiment of this invention. As shown in FIG. 1, a semiconductor substrate 10 such as a silicon substrate, silicon epitaxital substrate or Silicon-On-Insulator (SOI) substrate is provided. Shallow Trench Isolation (STI) 12 is provided and active area 13 is defined on the semiconductor substrate 10. A pad nitride layer 14 is then deposited on the semiconductor substrate 10. A dielectric layer 16 is then deposited on the pad nitride layer 14.

The pad nitride layer 14 may be formed by low-pressure CVD methods or other CVD methods. The pad nitride layer 14 has a thickness of about 100-500 angstroms. Optionally, prior to the deposition of the pad nitride layer 14, a layer of silicon oxide having a thickness of about 30-500 angstroms may be formed on the semiconductor substrate 10 by thermal oxidation or CVD methods.

According to the preferred embodiment of this invention, the dielectric layer 16 may be made of TEOS-based CVD oxide that is deposited by using tetra-ethyl-ortho-silicate as precursor, but not limited thereto.

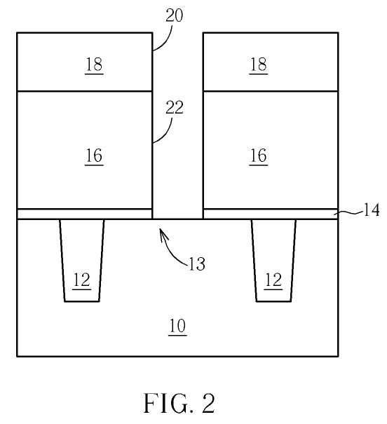

As shown in FIG. 2, a photoresist layer 18 is formed on the dielectric layer 16. A lithographic process is carried out to form an opening 20 in the photoresist layer 18. The opening 20 exposes a portion of the underlying dielectric layer 16. A dry etching process is then performed to etch the dielectric layer 16 and the pad nitride layer 14 through the opening 20 using the photoresist layer 18 as an etching hard mask, thereby forming an opening 22 in the dielectric layer 16 and the pad nitride layer 14 that exposes a portion of the semiconductor substrate 10.

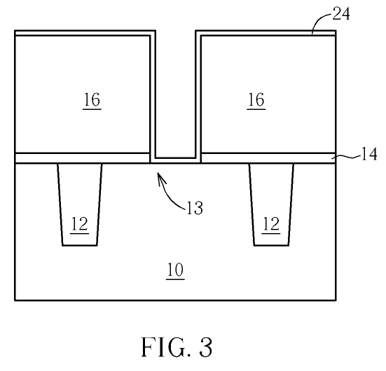

As shown in FIG. 3, after stripping the remaining photoresist layer 18, a CVD process is performed to deposit a conformal silicon nitride liner 24 on the dielectric layer 16 and on the sidewall and bottom of the opening 22. In accordance with the preferred embodiment of this invention, the silicon nitride liner 24 has a thickness of about 80-200 angstroms.

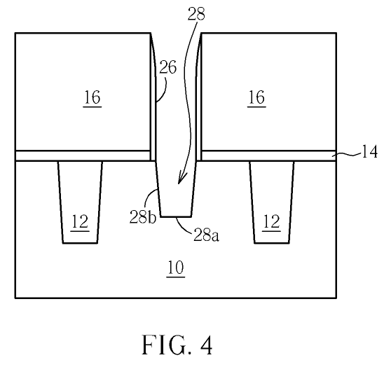

As shown in FIG. 4, an anisotropic dry etching process is performed to etch the silicon nitride liner 24. The silicon nitride liner 24 on the dielectric layer 16 and the silicon nitride liner 24 at the bottom of the opening 22 are both removed, leaving the silicon nitride liner 24 on the sidewall of the opening 22 substantially intact, thereby forming a silicon nitride spacer 26. The semiconductor substrate 10 at the bottom of the opening 22 is also etched to form a gate trench 28 comprising a trench bottom 28a and a trench sidewall 28b.

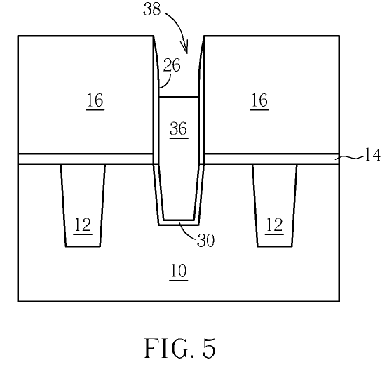

As shown in FIG. 5, a thermal oxidation process is carried out to form a sacrificing oxide layer (not shown) on the exposed trench bottom 28a and trench sidewall 28b of the gate trench 28. Thereafter, a channel implant is performed to adjust the threshold voltage of the device. After the channel implant, the sacrificing oxide layer is removed. Subsequently, a gate oxide layer 30 is formed on the exposed trench bottom 28a and trench sidewall 28b of the gate trench 28 by employing, for example, In-Situ Steam Growth (ISSG) technology.

After the formation of the gate oxide layer 30, the gate trench 28 is filled with conductive gate material 36 such as doped polysilicon. The conductive gate material 36 is then dry etched back to a pre-determined depth such that the top surface of the conductive gate material 36 is lower than the top surface of the dielectric layer 16, thereby forming a recess 38 between silicon nitride spacer 26 and the top surface of the conductive gate material 36.

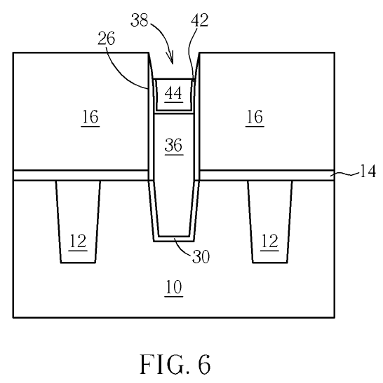

As shown in FIG. 6, according to the preferred embodiment, a Ti/WN composite metal layer 42 and a tungsten (W) metal layer 44 are deposited in the recess 38 atop the conductive gate material 36. After the deposition of the Ti/WN composite metal layer 42 and tungsten (W) metal layer 44, a dry etching process is performed to etch the Ti/WN composite metal layer 42 and tungsten (W) metal layer 44 to form a conductive structure atop the gate material 36 as set forth in FIG. 6. The top surface of the remaining tungsten (W) metal layer 44 is lower than the top surface of the dielectric layer 16.

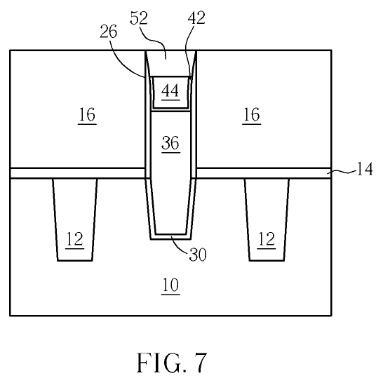

As shown in FIG. 7, a silicon nitride cap layer 52 is formed on the tungsten (W) metal layer 44. The silicon nitride cap layer 52 is formed by depositing a silicon nitride layer over the dielectric layer 16 and into the recess 38, followed by a planarization process such as an etching back process or Chemical Mechanical Polishing (CMP) process.

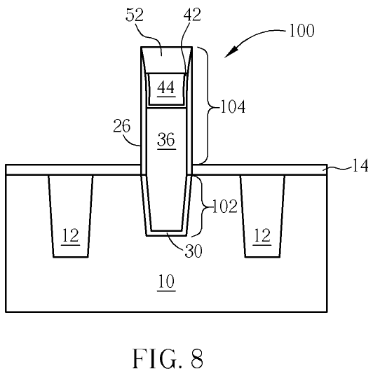

As shown in FIG. 8, a wet etching process such as diluted HF wet chemistry is employed to strip the dielectric layer 16, thereby forming recess gate 102 and the gate conductor 104 that is perfectly aligned with the recess gate 102 of the MOS transistor device 100.

From one aspect of this invention, the MOS transistor device 100 comprises a semiconductor substrate having a main surface, wherein a recess gate trench is formed on the main surface. A gate dielectric layer is formed on interior surface of the recess gate trench; A recess gate electrode 102 is embedded in the recess gate trench. A gate conductor 104 is disposed on the recess gate electrode and is aligned with the recess gate electrode above the main surface. The gate conductor is capped with a cap layer 52. A top surface area of the cap layer 52 is greater than a bottom surface area of the cap layer 52.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a recessed-gate transistor device, comprising:
forming a dielectric layer on a semiconductor substrate;
patterning said dielectric layer to form an opening exposing a portion of said semiconductor substrate, said opening has a bottom and a sidewall;
forming a liner on said bottom and said sidewall in said opening;
etching said liner at said bottom in said opening, thereby forming a spacer on said sidewall in said opening, and etching said semiconductor substrate to form a gate trench having a trench bottom and trench sidewall;
forming a gate oxide layer on said trench bottom and trench sidewall;
forming a gate material layer on said spacer and on said gate oxide layer in said gate trench;
forming a metal layer on said gate material layer;
forming a cap layer on said metal layer; and
removing said dielectric layer.

2. The method according to claim 1 wherein said spacer is silicon nitride spacer.

3. The method according to claim 2 wherein said silicon nitride spacerhas a thickness of about 80-200 angstroms.

4. The method according to claim 1 wherein said dielectric layer comprises TEOS-based oxide.

5. The method according to claim 1 further comprising a step of forming a pad nitride layer on said semiconductor substrate prior to forming said dielectric layer.

6. The method according to claim 1 wherein said liner is silicon nitride liner.

7. The method according to claim 1 wherein said gate oxide layer is formed by In-Situ Steam Growth (ISSG) method.

8. The method according to claim 1 wherein said gate material layer comprises doped polysilicon.

9. The method according to claim 1 wherein said metal layer comprises Ti/WN composite metal.

10. The method according to claim 1 wherein said metal layer comprises tungsten.

11. The method according to claim 1 wherein said cap layer is silicon nitride cap layer.

12. A recess-gate transistor device, comprising:
a semiconductor substrate having a main surface, wherein a recess gate trench is formed on said main surface;
a gate dielectric layer formed on interior surface of said recess gate trench;
a recess gate electrode embedded in said recess gate trench; and
a gate conductor on said recess gate electrode and being aligned with said recess gate electrode above said main surface.

13. A recess-gate transistor device, comprising:
a semiconductor substrate having a main surface, wherein a recess gate trench is formed on said main surface;
a gate dielectric layer formed on interior surface of said recess gate trench;
a recess gate electrode embedded in said recess gate trench; and
a gate conductor on said recess gate electrode and being aligned with said recess gate electrode above said main surface, wherein said gate conductor is capped with a cap layer and wherein a top surface area of said cap layer is greater than a bottom surface area of said cap layer.
